(19) United States
(12) Patent Application Publication
(10) Pub. No.: US 2023/0323133 A1
(43) Pub. Date: Oct. 12, 2023

(54) METAL-POLYMER HYBRID MATERIALS WITH A HIGH REFRACTIVE INDEX

(71) Applicant: 3M INNOVATIVE PROPERTIES COMPANY, St. Paul, MN (US)

(72) Inventors: Claire Hartmann-Thompson, Lake Elmo, MN (US); Mayank Puri, Minneapolis, MN (US)

(21) Appl. No.: 18/025,449

(22) PCT Filed: Oct. 7, 2021
(86) PCT No.: PCT/IB2021/059217

§ 371 Date: Mar. 9, 2023

Related U.S. Application Data
(60) Provisional application No. 63/089,214, filed on Oct. 8, 2020.

(51) Int. Cl. C09D 4/00; C09D 133/14; C09D 133/06; C09D 7/61; C08K 3/34; C08F 20/30; C08F 20/18; G02B 1/04

(52) U.S. Cl. CPC C09D 4/00; C09D 133/14; C09D 133/066; C09D 7/61; C08K 3/34; C08F 20/30; C08F 20/18; G02B 1/04; C08K 2003/343

(57) ABSTRACT

Coatable compositions contain metal-(meth)acrylate hybrid materials that when cured form a metal-polymer hybrid layer with a relatively high refractive index. The curable metal-(meth)acrylate hybrid composition includes a photoinitiator, a polyoxometalate and either a hydroxyl-functional (meth)acrylate or a mixture of hydroxyl-functional (meth)acrylate and aromatic (meth)acrylate. The printable, solvent-free composition, upon curing forms a metal-polymer hybrid layer that is optically transparent and has a refractive index of at least 1.52.

### FIELD OF THE DISCLOSURE

Disclosed herein are coatable compositions that contain metal-(meth)acrylate hybrid materials that when cured form a metal-polymer hybrid layer with a relatively high refractive index, and articles that contain the relatively high refractive index layers.

### BACKGROUND

Increasingly, optical devices are becoming more complicated and involve more and more functional layers. As light travels through the layers of the optical device, the light can be altered by the layers in a wide variety of ways. For example, light can be reflected, refracted or absorbed. In many cases, layers that are included in optical devices for non-optical reasons adversely affect the optical properties. For example, if a support layer is included that is not optically clear, the absorption of light by the non-optically support layer can adversely affect the light transmission of the entire device.

One common difficulty with multi-layer optical devices is that when layers of differing refractive indices are adjacent to each other, refraction of light can occur at their interface. In some devices this refraction of light is desirable, but in other devices the refraction is undesirable. In order to minimize or eliminate this refraction of light at the interface between two layers, efforts have been made to minimize the difference in refractive index between the two layers that form the interface. However, as a wider range of materials are employed within optical devices, the matching of refractive indices can become increasingly difficult. Organic polymer films and coatings, which are frequently used in optical devices, have a limited range of refractive indices. As higher refractive index materials are increasingly used in optical devices, it has become increasingly difficult to prepare organic polymeric compositions which have suitable refractive indices and yet retain the desirable features of organic polymers, features such as ease of processing, flexibility, and the like.

### SUMMARY

Disclosed herein are coatable compositions that contain metal-(meth)acrylate hybrid materials that when cured form a metal-polymer hybrid layer with a relatively high refractive index. In some embodiments, the curable metal-(meth)acrylate hybrid composition comprises at least one aromatic (meth)acrylate, at least one hydroxyl-functional (meth)acrylate, a polyoxometalate; and a photoinitiator. The composition is solvent-free, printable at a temperature of less than 50° C., and upon coating and curing forms a metal-polymer hybrid layer that is optically transparent and has a refractive index of at least 1.52.

In other embodiments, the curable metal-(meth)acrylate hybrid composition comprises at least one (meth)acrylate, wherein the (meth)acrylate comprises at least one hydroxyl group, a polyoxometalate, and a photoinitiator. The composition is solvent-free, printable at a temperature of less than 50° C., and upon coating and curing forms a metal-polymer hybrid layer that is optically transparent and has a refractive index of at least 1.52.

Also disclosed herein are articles. In some embodiments, the article comprises a substrate with a first major surface and a second major surface, and a metal-polymer hybrid layer adjacent to at least a portion of the second major surface of the substrate. The metal-polymer hybrid layer comprises a layer prepared from a coatable and curable composition, where the coatable and curable composition comprises a composition described above. In some embodiments, the coatable and curable composition comprises at least one (meth)acrylate comprising a (meth)acrylate comprising a hydroxyl group, or a mixture of (meth)acrylates comprising at least one aromatic (meth)acrylate and at least one hydroxyl-functional (meth)acrylate, a polyoxometalate, and a photoinitiator. The layer has a thickness of from 50 nanometers-16 micrometers, is optically transparent, and has a refractive index of at least 1.52.

### BRIEF DESCRIPTION OF THE DRAWINGS

The present application may be more completely understood in consideration of the following detailed description of various embodiments of the disclosure in connection with the accompanying drawings.

FIG. 1 is a cross sectional view of an optical article of this disclosure.

In the following description of the illustrated embodiments, reference is made to the accompanying drawings, in which is shown by way of illustration, various embodiments in which the disclosure may be practiced. It is to be understood that the embodiments may be utilized and structural changes may be made without departing from the scope of the present disclosure. The figures are not necessarily to scale. Like numbers used in the figures refer to like components. However, it will be understood that the use of a number to refer to a component in a given FIGURE is not intended to limit the component in another FIGURE labeled with the same number.

### DETAILED DESCRIPTION

The increased complexity of optical devices places increasingly difficult-to-meet requirements upon the materials used in them. In particular, organic polymeric materials have found widespread use in optical devices, but increasingly stringent requirements are being placed upon these polymeric materials.

For example, thin organic polymeric films are desirable for a wide range of uses in optical devices, as adhesives, protective layers, spacer layers, and the like. As articles have become more complex, the physical demands upon these layers have increased. For example, as optical devices have become more compact, and at the same time often include more layers, there has been an increasing need for thinner layers. At the same time, since the layers are thinner, the layers also need to be more precise. For example, a thin spacer layer (of 1 micrometer thickness) in order to be effective as a spacer needs to be level and free of gaps and holes in order to provide the proper spacing function. This requires deposition of the organic layer in a precise and consistent manner.

Additionally, not only do these layers have to supply their physical role (adhesion, protection, spacing, and the like) they must also provide the requisite optical properties. Among the properties that are becoming increasingly important is refractive index. As light travels through the layers of a multilayer article, it encounters the interface between layers. If the refractive indices of the layers are different, light can be refracted. Therefore, to minimize this refraction, matching of the refractive indices of layers within a multilayer article is desirable.

Since many layers within optical devices have refractive indices that are higher than typical organic polymer layers, much effort has been expended to develop organic polymer layers with higher refractive indices. However, often these organic polymer layers have drawbacks.

A number of techniques for preparing polymeric layers with a high refractive index using organic polymeric layers have been described. Typically, the methods have involved using high refractive index monomers, using high refractive index additives, or a combination of these methods. Each of the methods has advantages and drawbacks. Generally, high refractive index monomers suitable for making high refractive index polymers, such as aromatic monomers, are expensive and often have a high viscosity making it difficult to prepare coatable compositions with these monomers. Additionally, the use of high refractive index additives such as metal oxide nanoparticles, can increase the viscosity making it difficult to prepare coatable compositions, and also can reduce the flexibility and increase the brittleness of the layer making it less suitable as a thin optical layer.

Among the techniques used to produce polymeric layers with a high refractive index include organometallic polymeric materials such as those described in US Patent Publication No. 2015/0349295 (Boesch et al.). Boesch describes devices that utilize dyads as barrier coatings where the dyads include a first layer (decoupling layer) that is an organic-inorganic hybrid material and the second layer is an inorganic barrier layer. The organic-inorganic hybrid decoupling layer includes an organic matrix with either an organometallic polymer or inorganic nanoparticles such that the inorganic material raises the refractive index to better match the inorganic barrier layer refractive index.

The organometallic polymers used in the layers described by Boesch include metal atoms that are bonded to or reacted into an organic polymer to form an organometallic polymer. Some of these polymers are prepared from monomers, such as (meth)acrylate monomers, that have metal atoms bonded to them. The exemplary embodiment of Boesch uses a monomer blend that includes an acrylate monomer chemically bonded to Zr atoms. The monomer mixture was spin coated, heated and UV-cured. The curable compositions of Boesch generally have a high viscosity.

In this disclosure, coatable compositions are described that are curable metal-(meth)acrylate hybrid compositions. These compositions are hybrids of POM (polyoxometalates) and (meth)acrylates. POM materials have a high refractive index but as solid materials, their usefulness in curable compositions has the same drawbacks as the inorganic metal oxide particles described above. In the current curable compositions, the POM is a part of a metal-(meth)acrylate hybrid, meaning that the POM materials are linked to (meth)acrylates and thus are solubilized, such that the POM-(meth)acrylate hybrid compositions are fluid materials. Therefore, unlike compositions that include particles such as metal oxide nanoparticles, the current hybrid compositions are fluids capable of being coated and printed. In this way, many common issues associated with nanoparticle usage in optical materials are avoided: agglomeration resulting in increased haze and decreased transmission; necessity to surface-treat the nanoparticles to optimize compatibility with the surrounding polymer matrix; increased viscosity/hardness/brittleness; increased difficulty in processing; and decreased flexibility.

The POM-(meth)acrylate hybrid compositions not only overcome the common issues described above, it has surprisingly been found that even a small quantity of hydroxyl-functional (meth)acrylates can solubilize the otherwise insoluble POM materials. Additional (meth)acrylate monomers, including aromatic (meth)acrylate monomers that also tend to be higher refractive index monomers, can be added to further modify the properties of the compositions.

In some embodiments the compositions have 2 components: POM; and a hydroxyl-functional (meth)acrylate. The hydroxyl-functional (meth)acrylate can be a hydroxyl-functional alkyl (meth)acrylate or it can be hydroxyl-functional (meth)acrylate that also contains one or more aromatic groups. In other embodiments, the compositions have 3 components: POM; a hydroxyl-functional (meth)acrylate; and an aromatic (meth)acrylate. The compositions also include a photointiator to cure the compositions. The cured compositions are transparent and have a refractive index of at least 1.52. The curable compositions can be coated and cured to form layers in optical articles. Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. For example, reference to “a layer” encompasses embodiments having one, two or more layers. As used in this specification and the appended claims, the term “or” is generally employed in its sense including “and/or” unless the content clearly dictates otherwise.

The term “(meth)acrylate” refers to monomeric acrylic or methacrylic esters of alcohols. Acrylate and methacrylate monomers or oligomers are referred to collectively herein as “(meth)acrylates”. Materials referred to as “(meth)acrylate functional” are materials that contain one or more (meth)acrylate groups.

The terms “room temperature” and “ambient temperature” are used interchangeably to mean temperatures in the range of 20° C. to 25° C.

The term “adjacent” as used herein when referring to two layers means that the two layers are in proximity with one another with no intervening open space between them. They may be in direct contact with one another (e.g. laminated together) or there may be intervening layers.

The term “polymer” is used herein consistent with its common usage in chemistry. A polymer is composed of many repeated subunits and is the resultant material formed from a polymerization reaction.

The term “alkyl” refers to a monovalent group that is a radical of an alkane, which is a saturated hydrocarbon. The alkyl can be linear, branched, cyclic, or combinations thereof and typically has 1 to 20 carbon atoms. In some embodiments, the alkyl group contains 1 to 18, 1 to 12, 1 to 10, 1 to 8, 1 to 6, or 1 to 4 carbon atoms. Examples of alkyl groups include, but are not limited to, methyl, ethyl, n-propyl, isopropyl, n-butyl, isobutyl, tert-butyl, n-pentyl, n-hexyl, cyclohexyl, n-heptyl, n-octyl, and ethylhexyl.

The term “aryl” refers to a monovalent group that is aromatic and carbocyclic or carbocyclic with heteroatom ring substitution. The aryl can have one to five rings that are connected to or fused to the aromatic ring. The other ring structures can be aromatic, non-aromatic, or combinations thereof. Examples of aryl groups include, but are not limited to, phenyl, biphenyl, terphenyl, anthryl, naphthyl, acenaphthyl, anthraquinonyl, phenanthryl, anthracenyl, pyrenyl, perylenyl, and fluorenyl. In some embodiments, the aromatic rings may contain one or more heteroatom ring substituents, such as nitrogen, oxygen, or sulfur. Examples of carbocyclic aromatic rings with heteroatom ring substitution include pyridine, furan, and thiophene.

The term “alkylene” refers to a divalent group that is a radical of an alkane. The alkylene can be straight-chained, branched, cyclic, or combinations thereof. The alkylene often has 1 to 20 carbon atoms. In some embodiments, the alkylene contains 1 to 18, 1 to 12, 1 to 10, 1 to 8, 1 to 6, or 1 to 4 carbon atoms. The radical centers of the alkylene can be on the same carbon atom (i.e., an alkylidene) or on different carbon atoms.

The term “arylene” refers to a divalent group that is aromatic and carbocyclic or carbocyclic with heteroatom ring substitution. The group has one to five rings that are connected, fused, or combinations thereof. The other rings can be aromatic, non-aromatic, or combinations thereof. In some embodiments, the arylene group has up to 5 rings, up to 4 rings, up to 3 rings, up to 2 rings, or one aromatic ring. For example, the arylene group can be phenylene.

The term “heteroalkylene” refers to a divalent group that includes at least two alkylene groups connected by a thio, oxy, or —NR— where R is alkyl. The heteroalkylene can be linear, branched, cyclic, substituted with alkyl groups, or combinations thereof. Some heteroalkylenes are polyoxyalkylenes where the heteroatom is oxygen such as for example,

—CH₂CH₂(OCH₂CH₂)ₙOCH₂CH₂—.

The term “aralkylene” refers to a divalent group of formula —R^{a}—Ar^{a}— where R^{a} is an alkylene and Ar^{a} is an arylene (i.e., an alkylene is bonded to an arylene).

The term “heteroarylene” refers to a divalent group that is an arylene group containing heteroatoms such as sulfur, oxygen, nitrogen or halogens such as fluorine, chlorine, bromine or iodine.

Unless otherwise indicated, the terms “optically transparent”, and “visible light transmissive” are used interchangeably, and refer to an article, film or adhesive that has a high light transmittance over at least a portion of the visible light spectrum (about 400 to about 700 nm). Typically, optically transparent articles have a visible light transmittance of at least 90% and a haze of less than 10%.

Unless otherwise indicated, “optically clear” refers to an adhesive or article that has a high light transmittance over at least a portion of the visible light spectrum (about 400 to about 700 nm), and that exhibits low haze, typically less than about 5%, or even less than about 2%. In some embodiments, optically clear articles exhibit a haze of less than 1% at a thickness of 50 micrometers or even 0.5% at a thickness of 50 micrometers. Typically, optically clear articles have a visible light transmittance of at least 95%, often higher such as 97%, 98% or even 99% or higher.

Disclosed herein are curable metal-(meth)acrylate hybrid compositions. The metal-(meth)acrylate hybrid compositions are coatable fluids. Typically, the curable compositions of the present disclosure are “100% solids”, meaning that they do not contain volatile solvents and that all of the mass that is deposited on a surface remains there, no volatile mass is lost from the coating. The terms “coatable compositions” and “ink” are used interchangeably in this disclosure. In some embodiments, the polyoxometalate (POM) is neutralized with base, such as sodium hydroxide. In these embodiments, small quantities of water are typically added to solubilize the base.

The curable compositions of the present disclosure are useful as inks, meaning that they are capable of being printed by for example inkjet printing techniques without the use of solvents at a temperature of from room temperature to 50° C., or even from room temperature to 35° C. Typically, the printable curable composition has a viscosity at these temperatures of 30 centipoise or less.

The curable compositions are “substantially solvent free” or “solvent free”. As used herein, “substantially solvent free” refers to the curable ink compositions having less than 5 wt-%, 4 wt-%, 3 wt-%, 2 wt-%, 1 wt-% and 0.5 wt-% of non-polymerizable (e.g. organic) solvent. The concentration of solvent can be determined by known methods, such as gas chromatography (as described in ASTM D5403). The term “solvent free” as it implies that no solvent is present in the composition. It should be noted that whether the curable composition is substantially solvent free or solvent free, no solvent is deliberately added.

The curable compositions are printable, and thus can be described as inks. The curable compositions need not be used as inks, that is to say that they need not be printed and then cured, the curable compositions can be delivered to substrate surfaces in a wide variety of ways, but they are capable of being printed. In particular the printable compositions of this disclosure are typically capable of being inkjet printed, which means that they have the proper viscosity and other attributes to be inkjet printed. The term “inkjet printable” is not a process description or limitation, but rather is a material description, meaning that the curable compositions are capable of being inkjet printed, and not that the compositions necessarily have been inkjet printed. This is akin to the expression hot melt processable, which means that a composition is capable of being hot melt processed but does not mean that the composition has been hot melt processed.

The curable compositions comprise as reactive components, at least a polyoxometalate (POM) and a hydroxyl-functional (meth)acylate. The curable compositions also comprise at least one photointiator to effect curing of the curable compositions. A wide range of formulation latitude is disclosed herein. In some embodiments, the curable compositions are called 2-component compositions, meaning that they comprise a POM and at least one hydroxyl-functional (meth)acrylate. In other embodiments, the curable compositions are called 3-component compositions, meaning that they comprise a POM, at least one hydroxyl-functional (meth)acrylate, and at least one aromatic (meth)acrylate. A wide variety of hydroxyl-functional (meth)acrylates and aromatic (meth)acrylates are suitable as is described in greater detail below.

The curable compositions of the current disclosure comprise a polyoxometalate (POM) as a high refractive index additive. POMs are highly polar inorganic protic acid species that are solids and are normally incompatible and immiscible with high refractive index aromatic organic (meth)acrylates. It has been found that combination of the POM with a hydroxyl-functional (meth)acrylate solubilizes the POM and provides a fluid composition. It has further been found that the POM can be solubilized not only in its acidic form, but also when the POM is neutralized with sodium hydroxide.

A wide range of polyoxometalates are suitable for preparing the coatable compositions of this disclosure. Polyoxometalate (abbreviated POM) is a polyatomic ion, usually an anion, that consists of three or more transition metal oxyanions linked together by shared oxygen atoms to form closed 3-dimensional frameworks. Two broad families are recognized, isopolymetalates, composed of only one kind of metal and oxide, and heteropolymetalates, composed of one metal, oxide, and a main group oxyanion (phosphate, silicate, etc.).

Typically, the polyoxometalates of this disclosure comprise a polyoxometalate of tungsten, molybdenum, vanadium, tantalum or niobium. Especially suitable polyoxometalates are polyoxometalates of tungsten or molybdenum. One particularly suitable polyoxometalate comprises a tungstosilic acid.

As was described above, the curable composition further comprises at least one hydroxyl-functional (meth)acrylate. The curable composition embodiments that include POM, at least one hydroxyl-functional (meth)acrylate, and a photoinitiator are referred to herein as 2-component compositions.

A wide range of hydroxyl-functional (meth)acrylates are suitable. In some embodiments, the 2-component compositions comprise a single hydroxyl-functional (meth)acrylate, in other embodiments the hydroxyl-functional (meth)acrylate comprises a mixture of hydroxyl-functional (meth)acrylates.

Suitable hydroxyl-functional (meth)acrylates include hydroxyl-functional alkyl (meth)acrylates as well as hydroxyl-functional (meth)acrylates that have a hydroxyl functional aromatic group or group comprising an aromatic group and a hydroxyl group.

The hydroxyl-functional (meth)acrylate comprises a (meth)acrylate of general formula 2:

H₂C═CHR¹—(CO)—O—R³ Formula 2

wherein R¹ is a hydrogen atom or a methyl group; and R³ is a hydroxyl-functional moiety comprising an alkylene group, a heteroalkylene group, an aralkylene, a heteroarylene group, or a combination of groups.

In some embodiments, the hydroxyl-functional (meth)acrylate of Formula 2 is a hydroxyl-functional alkyl (meth)acrylate. Examples of hydroxyl-functional alkyl (meth)acrylates are those where R³ is a group comprising —(CH₂)ₐ—CH₂OH, wherein a is an integer of 1 or greater. Examples include hydroxyethyl acrylate (HEA), hydroxyethyl methacrylate (HEMA), hydroxybutyl acrylate, and polypropyleneglycol (meth)acrylate.

In other embodiments, the hydroxyl-functional (meth)acrylate includes a hydroxyl group or hydroxyl groups and at least one aromatic group. Examples of hydroxyl-functional (meth)acrylate with at least one aromatic group include (meth)acrylates of general Formula 3:

H₂C═CHR¹—(CO)—O—Ar^{OH} Formula 3

where R¹ is a hydrogen atom or a methyl group; and Ar^{OH} is a hydroxyl functional aromatic group or group comprising an aromatic group and a hydroxyl group. In some embodiments, the Ar^{OH} group comprises: a group comprising —(CH₂)ₐ—(CH(OH))—(CH₂)_{b}—O-Ph, where a is an integer of 1 or greater; b is an integer of 1 or greater; and Ph is a phenyl group or substituted phenyl group.

As mentioned above, the embodiments of 2-component curable compositions may comprise a single hydroxyl-functional (meth)acrylate or it may comprise a combination of hydroxyl-functional (meth)acrylates. The addition of aromatic-containing hydroxyl-functional (meth)acrylates can help to raise the refractive index of the cured composition. Some particularly suitable 2-component curable compositions include POM and an aromatic-containing hydroxyl-functional (meth)acrylate.

Also disclosed herein are curable metal-(meth)acrylate 3-component hybrid compositions. The curable metal-(meth)acrylate hybrid compositions comprise at least one aromatic (meth)acrylate, at least one hydroxyl-functional (meth)acrylate, a polyoxometalate; and a photoinitiator. Like the 2-component curable compositions described above, the 3-component compositions are solvent-free, printable at a temperature of less than 50° C., and upon coating forms a layer that is optically transparent and has a refractive index of at least 1.52.

The POM component and hydroxyl-functional (meth)acrylate components have been described above. The 3-component compositions also comprise at least one aromatic (meth)acrylate. A wide range of aromatic (meth)acrylates are suitable. The at least one aromatic (meth)acrylate comprises an aromatic (meth)acrylate of general formula 1:

H₂C═CHR¹—(CO)—O—Ar Formula 1

where R¹ is a hydrogen atom or a methyl group; and Ar is an aromatic group comprising a phenyl group, a substituted phenyl group, an arylene group or a heteroarylene group. In some embodiments, Ar comprises an arylene or heteroarylene group comprising: an arylene or heteroarylene group comprising —(CH₂)ₙ—(C₆R²₄)—Z—(C₆R²₅); where n is integer of 1 or greater; each R² is independently a hydrogen atom or alkyl group; Z is single bond or an oxygen or sulfur atom. In other embodiments, Ar is a heteroarylene group comprising —(CH₂—CH₂)-T-(C₆R²₄)—Z—(C₆R²₅), wherein T is an oxygen or sulfur atom; each R² is independently a hydrogen atom or alkyl group; and Z is single bond or an oxygen or sulfur atom.

The curable compositions also comprise at least one photoinitiator, meaning that the initiator is activated by light, typically ultraviolet (UV) light. Photoinitiators are well understood by one of skill in the art of (meth)acrylate polymerization. Examples of suitable free radical photoinitiators include DAROCURE 4265, IRGACURE 184, IRGACURE 651, IRGACURE 1173, IRGACURE 819, LUCIRIN TPO, LUCIRIN TPO-L, commercially available from BASF, Charlotte, NC.

Generally, the photoinitiator is used in amounts of 0.01 to 1 parts by weight, more typically 0.1 to 0.5 parts by weight relative to 100 parts by weight of total reactive components.

The curable composition may contain additional reactive or unreactive components, but such components are not necessary and may be detrimental to the final properties of the formed (meth)acrylate-based polymer. As mentioned above, the curable ink composition is substantially free or free of solvent.

Also disclosed herein are articles, particularly multilayer articles. In some embodiments, the article comprises a substrate with a first major surface and a second major surface and a cured metal-polymer hybrid layer adjacent to at least a portion of the second major surface. The cured metal-polymer hybrid layer comprises a layer prepared from a coatable and curable composition, where the coatable curable composition comprises a 2-component or 3-component curable composition described above. In some embodiments, the coatable, curable composition comprises at least one (meth)acrylate comprising a (meth)acrylate comprising a hydroxyl group, or a mixture of (meth)acrylates comprising at least one aromatic (meth)acrylate and at least one hydroxyl-functional (meth)acrylate, a polyoxometalate, and a photoinitiator. The cured layer has a thickness of from 50 nanometers-16 micrometers, is optically transparent, and has a refractive index of at least 1.52.

In some embodiments, the article further comprises a device disposed on the second major surface of the substrate, and adjacent to the metal-polymer hybrid layer. A wide variety of devices are suitable. In some embodiments, the device an OLED (organic light-emitting diode), a quantum dot light emitting diode, a micro light emitting diode, or a quantum nanorod electronic device.

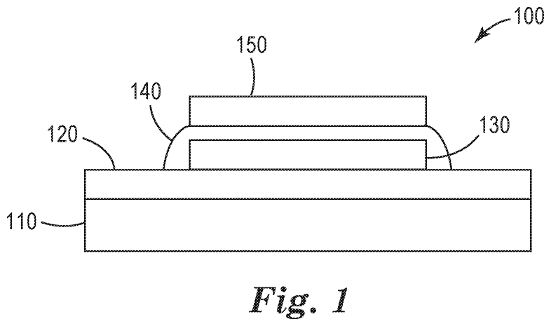

An exemplary embodiment of an article of the present disclosure is shown in FIG. 1. FIG. 1 shows exemplary electronic device 100 comprising an optical electronic component in the form of an OLED display. OLED display 130 supported on Thin Film Transistor (TFT) 120 array on an OLED mother glass substrate 110. Thin Film Encapsulation (TFE) layer 140 comprises a cured composition according to the present disclosure composition. Layer 140 is disposed on and encapsulates OLED display 130. Touch sensor assembly (e.g., an On-Cell Touch Assembly (OCTA)) 150 is disposed on cured composition 140.

### Examples

These examples are merely for illustrative purposes only and are not meant to be limiting on the scope of the appended claims. All parts, percentages, ratios, etc. in the examples and the rest of the specification are by weight, unless noted otherwise. The following abbreviations are used: mm=millimeters; nm=nanometers; mL=milliliters; g=grams; mg=milligrams; s=seconds; min=minutes; hrs=hours; cps=centiPoise. The terms “weight %”, “% by weight”, and “wt %” are used interchangeably.

TABLE A
Description of materials

| Abbreviation | Material | Source (Location) |
|---|---|---|
| TAH | 12-Tungstosilicic acid hydrate | Product number 39651 from Alfa Aesar |
| | | (Tewksbury, MA) |
| TPH | 12-Tungstophosphate hydrate | Product number 11827 from Alfa Aesar |
| | | (Tewksbury, MA) |
| PBA | Phenoxybenzyl acrylate | KONOMER A008 from KPX Green |
| | | Chemical Co. (Chungcheongnam-do, |
| | | Korea) |
| OPPEA | O-Phenyl phenol ethylacrylate | KONOMER A011 from KPX Green |
| | | Chemical Co. (Chungcheongnam-do, |
| | | Korea) |
| BPMA | Biphenyl methylacrylate | MIRAMER M1192H from Miwon Inc. |
| | | Exton, PA. |
| PTPBA | Para-thiophenyl benzyl acrylate | Synthesized as described in U.S. Pat. |
| | | Publication No. 2019/0352520. |
| HEMA | Hydroxyethylmethacrylate | Product number M0085 from TCI America |
| | | (Portland, OR) |
| HPPA | 2-Hydroxy-3-phenoxy propyl | NK ESTER 702A from Shin Nakamura |
| | acrylate | Chemical Co. Ltd/Kowa (Tokyo, Japan) |
| PI | Photoinitiator 2,4,6- | Available under the trade designation |
| | Trimethylbenzoylphenyl- | LUCIRIN TPO-L from BASF (Florham |
| | phosphinic acid ethyl ester | Park, NJ, USA) |
| NaOH | 1N sodium hydroxide solution | Available from VWR (Radnor, PA, USA) |
| | | under the trade designations J. T. BAKER |
| | | and BAKER ANALYZED REAGENT |

### Preparation of Formulations

Formulations were prepared by mixing the components in sealed glass vials with a magnetic stir bar at room temperature for 2 hrs. pH was measured using indicator paper (Ricca Chemical Company pH test strip 0-14, product no. 8880-1).

### Refractive Index Measurements

The refractive index was measured on a Milton Roy Company refractometer (model number: 334610). The liquid sample was sealed between two prisms and the refractive index was measured at 23° C. at the 589 nm line of a sodium lamp.

### Viscosity Measurements

Rheological measurements were conducted according to ASTM D7867-13 test method A on an ARES G2 strain-controlled rheometer using a recessed concentric cylinder geometry (bob of 25 mm diameter and 32 mm length; cup with 27 mm diameter). The measurements were collected at 25 and 50° C. under nitrogen atmosphere. The measurements were obtained at a shear rate of 10 s⁻¹.

### UV-Cured Formulations

Liquid formulations were UV-cured by addition of 1 weight percent (based on polymer solids) PI photo initiator, coated onto a glass slide, and passed through a Light Hammer (LHC10 Mark 2) UV processor (Fusion UV Systems Inc., Gaithersburg, MD) using a “D-bulb” with three passes of the conveyor belt running at 50 feet per minute (15 meters per minute). After cure, transparent solid coatings were obtained.

### Examples and Comparative Examples

Example liquid formulations were prepared with POM (with POM are labeled with an E) or without POM (without POM are labeled as Comparative with a C) as described in Table 1.

TABLE 1
Refractive indices and viscosities of formulations based on aromatic
(meth)acrylates (PBA, OPPEA, BPMA, PTPBA), hydroxyl-(meth)acrylates
(HEMA and HPPA) and POMs (TAH unless otherwise specified).

| | | | | Viscosity | Viscosity |
|---|---|---|---|---|---|
| Example | | Wt. % | Refractive | (cps) | (cps) |
| Solution | (Meth)acrylate | POM | index | RT | 50° C. |
| C1 | HEMA | 0 | 1.446 | 10 | — |
| E1A | | 84 | 1.593 | 240 | 86 |
| E1B | | 62 (TPH) | 1.547 | 402 | 109 |
| C2 | HPPA 702A | 0 | 1.522 | 177 | 23 |
| E2A | | 80 | 1.621 | 4350 | 616 |
| C3 | PBA A008 | 0 | 1.562 | 18 | <10 |
| C4 | 77/23 | 0 | 1.553 | 25 | 9 |
| E4A | PBA/HPPA | 63 | 1.613 | 3290 | 379 |
| C5 | 50/50 | 0 | 1.542 | 44 | 11 |
| E5A | PBA/HPPA | 71 | 1.613 | — | — |
| | | 75 | 1.620 | 6400 | 190 |
| C6 | OPPEA A011 | 0 | 1.574 | 150 | 26 |
| C7 | 89/11 | 0 | 1.569 | 144 | 23 |
| E7A | OPPEA/HPPA | 61 | 1.620 | 6510 | 527 |
| C8 | 50/50 | 0 | 1.549 | 140 | 20 |
| E8A | OPPEA/HPPA | 72 | 1.620 | | |
| | | 76 | 1.627 | 9400 | 930 |
| C9 | PTPBA | 0 | 1.602 | 14 | <10 |
| C10 | 86/14 | 0 | 1.593 | 23 | 11 |
| E10A | PTPBA/HPPA | 39 | 1.635 | 607,000 | 15,900 |
| C11 | 50/50 | 0 | 1.561 | 44 | 12 |
| E11A | PTPBA/HPPA | 61 | 1.619 | — | — |
| E11B | | 65 | 1.626 | 400,000 | 25,000 |
| C12 | BPMA | 0 | 1.603 | 36 | 15 |
| C13 | 83/17 | 0 | 1.585 | 16 | 49 |
| E12A | BPMA/HPPA | 25 | 1.607 | — | — |

### Examples with Neutralized POMs

Example liquid formulations were prepared with (with POM are labeled with an E) or without neutralized POM (without POM are labeled as Comparative with a C) as described in Table 2.

TABLE 2
Refractive indices and pH of formulations where the POMs have been
neutralized with sodium hydroxide (6.7 molar excess relative to TAH).

| | | | | | | | Re- |
|---|---|---|---|---|---|---|---|
| Ex- | Component | | | | | | frac- |
| am- | | | | 1N | | | tive |
| ple | HPPA | HEMA | Water | NaOH | TAH | pH | index |
| C14 | 2.66 mL | 0 mL | 0.34 mL | 93 mg | 0 g | 12 | 1.515 |
| E13A | 2.66 mL | 0 mL | 0.34 mL | 93 mg | 1 g | 5 | 1.522 |
| C15 | 0 mL | 1.66 mL | 0.34 mL | 93 mg | 0 g | 12 | 1.434 |
| E14A | 0 mL | 1.66 mL | 0.34 mL | 93 mg | 1 g | 5 | 1.462 |

What is claimed is:

1. A curable metal-(meth)acrylate hybrid composition comprising:
at least one aromatic (meth)acrylate;
at least one hydroxyl-functional (meth)acrylate′
a polyoxometalate; and
a photoinitiator; wherein the composition is solvent-free, printable at a temperature of
less than 50° C., and upon coating forms a layer that is optically transparent and has a refractive index of at least 1.52.

2. The curable metal-(meth)acrylate hybrid composition of claim 1, wherein the polyoxometalate is an anion of tungsten, molybdenum, vanadium, tantalum or niobium.

3. The curable metal-(meth)acrylate hybrid composition of claim 1, wherein the polyoxometalate comprises a polyoxometalate of tungsten or molybdenum.

4. The curable metal-(meth)acrylate hybrid composition of claim 1, wherein the polyoxometalate comprises a tungstosilic acid.

5. The curable metal-(meth)acrylate hybrid composition of claim 1, wherein the at least one aromatic (meth)acrylate comprises an aromatic (meth)acrylate of general formula 1:
H₂C═CHR¹—(CO)—O—Ar Formula 1
wherein R¹ is a hydrogen atom or a methyl group; and
Ar is an aromatic group comprising a phenyl group, a substituted phenyl group, an arylene group or a heteroarylene group.

6. The curable metal-(meth)acrylate hybrid composition of claim 5, wherein Ar comprises
an arylene or heteroarylene group comprising:
an arylene or heteroarylene group comprising —(CH₂)ₙ—(C₆R²₄)—Z—(C₆R²₅),
wherein n is integer of 1 or greater;
each R² is independently a hydrogen atom or alkyl group;
Z is single bond or an oxygen or sulfur atom; or
a heteroarylene group comprising —(CH₂—CH₂)-T-(C₆R²₄)—Z—(C₆R²₅),
wherein T is an oxygen or sulfur atom;
each R² is independently a hydrogen atom or alkyl group; and
Z is single bond or an oxygen or sulfur atom.

7. The curable metal-(meth)acrylate hybrid composition of claim 1, wherein the hydroxyl-functional (meth)acrylate comprises a (meth)acrylate of general formula 2:
H₂C═CHR¹—(CO)—O—R³ Formula 2
wherein R¹ is a hydrogen atom or a methyl group; and
R³ is a hydroxyl-functional moiety comprising an alkylene group, a heteroalkylene group, an aralkylene group, or a combination of groups.

8. The curable metal-(meth)acrylate hybrid composition of claim 7, wherein the hydroxyl-functional moiety comprises:
a group comprising —(CH₂)ₐ—CH₂OH,
wherein a is an integer of 1 or greater;
a group comprising —(CH₂)ₐ—(CH(OH))—(CH₂)_{b}—O-Ph,
wherein a is an integer of 1 or greater;
b is an integer of 1 or greater; and
Ph is a phenyl group or substituted phenyl group.

9. A curable metal-(meth)acrylate hybrid composition comprising:
at least one (meth)acrylate, wherein the (meth)acrylate comprises at least one hydroxyl group;
a polyoxometalate; and
a photoinitiator; wherein the composition is solvent-free, printable at a temperature of less than 50° C., and upon coating forms a layer that is optically transparent and has a refractive index of at least 1.52.

10. The curable metal-(meth)acrylate hybrid composition of claim 9, wherein the polyoxometalate is an anion of tungsten, molybdenum, vanadium, tantalum or niobium.

11. The curable metal-(meth)acrylate hybrid composition of claim 9, wherein the polyoxometalate comprises a polyoxometalate of tungsten or molybdenum.

12. The curable metal-(meth)acrylate hybrid composition of claim 9, wherein the polyoxometalate comprises a tungstosilic acid.

13. The curable metal-(meth)acrylate hybrid composition of claim 9, wherein the (meth)acrylate comprising at least one hydroxyl group comprises a hydroxyl-functional alkyl (meth)acrylate.

14. The curable metal-(meth)acrylate hybrid composition of claim 9, wherein the (meth)acrylate comprising at least one hydroxyl group comprises an aromatic (meth)acrylate of general formula 3:
H₂C═CHR¹—(CO)—O—Ar^{OH} Formula 3
wherein R¹ is a hydrogen atom or a methyl group; and
Ar^{OH} is a hydroxyl functional aromatic group or group comprising an aromatic group and a hydroxyl group.

15. The curable metal-(meth)acrylate hybrid composition of claim 14, wherein the Arm group comprises:
a group comprising —(CH₂)ₐ—(CH(OH))—(CH₂)_{b}—O-Ph,
wherein a is an integer of 1 or greater;
b is an integer of 1 or greater; and
Ph is a phenyl group or substituted phenyl group.

16. An article comprising:
a substrate with a first major surface and a second major surface;
a metal-polymer hybrid layer adjacent to at least a portion of the second major surface
of the substrate, wherein the metal-polymer hybrid layer comprises a layer prepared
from a coatable and curable composition, wherein the coatable and curable composition comprises:
at least one (meth)acrylate comprising;
a (meth)acrylate comprising a hydroxyl group; or
a mixture of (meth)acrylates comprising at least one aromatic (meth)acrylate and at least one hydroxyl-functional (meth)acrylate;
a polyoxometalate; and
a photoinitiator; wherein the layer has a thickness of from 50 nanometers −16
micrometers, is optically transparent, and has a refractive index of at least 1.52.

17. The article of claim 16, wherein the article further comprises a device disposed on the second major surface of the substrate, and adjacent to the metal-polymer hybrid layer.

18. The article of claim 17, wherein the device comprises an OLED (organic light-emitting diode), a quantum dot light emitting diode, a micro light emitting diode, or a quantum nanorod electronic device.

19. The article of claim 16, wherein the at least one (meth)acrylate comprises a hydroxyl-functional alkyl (meth)acrylate or a (meth)acrylate comprising an aromatic group and a hydroxyl group of general Formula 3:
H₂C═CHR¹—(CO)—O—Ar^{OH} Formula 3
wherein R¹ is a hydrogen atom or a methyl group; and
Ar^{OH} is a group comprising —(CH₂)ₐ—(CH(OH))—(CH₂)_{b}—O-Ph,
wherein a is an integer of 1 or greater;
b is an integer of 1 or greater; and
Ph is a phenyl group or substituted phenyl group.

20. The article of claim 16, wherein the at least one (meth)acrylate comprises a mixture comprising at least one aromatic (meth)acrylate of general formula 1:
H₂C═CHR¹—(CO)—O—Ar Formula 1
wherein R′ is a hydrogen atom or a methyl group; and
Ar is an aromatic group comprising a phenyl group, a substituted phenyl group, an arylene group or a heteroarylene group, wherein the arylene or heteroarylene group comprises:
an arylene or heteroarylene group comprising—(CH₂)ₙ—(C₆R²₄)—Z—(C₆R²₅),
wherein n is integer of 1 or greater;
each R² is independently a hydrogen atom or alkyl group;
Z is single bond or an oxygen or sulfur atom; or
a heteroarylene group comprising —(CH₂—CH₂)-T-(C₆R²₄)—Z—(C₆R²₅),
wherein T is an oxygen or sulfur atom;
each R² is independently a hydrogen atom or alkyl group; and
Z is single bond or an oxygen or sulfur atom; and
a hydroxyl-functional (meth)acrylate of general formula 2:
H₂C═CHR¹—(CO)—O—R³ Formula 2
wherein R′ is a hydrogen atom or a methyl group; and
R³ is a hydroxyl-functional moiety comprising:
a group comprising —(CH₂)ₐ—CH₂OH,
wherein a is an integer of 1 or greater;
a group comprising —(CH₂)ₐ—(CH(OH))—(CH₂)_{b}—O-Ph,
wherein a is an integer of 1 or greater;
b is an integer of 1 or greater; and
Ph is a phenyl group or substituted phenyl group.

21. The article of claim 16, wherein the polyoxometalate is an anion of tungsten, molybdenum, vanadium, tantalum or niobium.
